(19) United States
(12) Patent Application Publication
(10) Pub. No.: US 2024/0112947 A1
(43) Pub. Date: Apr. 4, 2024

(54) SHALLOW TRENCH ISOLATION (STI) PROCESSING WITH LOCAL OXIDATION OF SILICON (LOCOS)

(71) Applicant: TEXAS INSTRUMENTS INCORPORATED, Dallas, TX (US)

(72) Inventors: Scott Kelly Montgomery, Rowlett, TX (US); James Todd, Plano, TX (US); Yanbiao Pan, Plano, TX (US); Jeffery Nilles, Los Altos, CA (US)

(21) Appl. No.: 17/977,250

(22) Filed: Oct. 31, 2022

Related U.S. Application Data
(60) Provisional application No. 63/411,438, filed on Sep. 29, 2022.

(51) Int. Cl. H01L 21/762; H01L 27/06

(52) U.S. Cl. CPC H01L 21/76224; H01L 27/0629

(57) ABSTRACT

The present disclosure generally relates to shallow trench isolation (STI) processing with local oxidation of silicon (LOCOS), and an integrated circuit formed thereby. In an example, an integrated circuit includes a semiconductor layer, a LOCOS layer, an STI structure, and a passive circuit component. The semiconductor layer is over a substrate. The LOCOS layer is over the semiconductor layer. The STI structure extends into the semiconductor layer. The passive circuit component is over and touches the LOCOS layer.

### CROSS-REFERENCE TO RELATED APPLICATIONS

This application claims priority to and the benefit of U.S. Provisional Patent Application Ser. No. 63/411,438, filed on Sep. 29, 2022, which is hereby incorporated herein by reference in its entirety. This application is related to U.S. Pat. No. 11,296,075, which is hereby incorporated herein by reference in its entirety.

### BACKGROUND

Defects in shallow trench isolation (STI) structures can affect components in an integrated circuit or other packaged electronic device. Cone defects in the STI may be caused by particles of a hardmask or photoresist or other residue remaining during a trench etch process where a trench for an STI structure is to be etched, which can create a region of the substrate that unintentionally did not get etched. Resistors or capacitors formed over STI structures are susceptible to oxide stress failures of the STI structures if a cone defect is present under these components.

### SUMMARY

This Summary is provided to introduce a brief selection of disclosed concepts in a simplified form that are further described below in the Detailed Description including the drawings provided. Various disclosed devices and methods may be beneficially applied to an integrated circuit that includes a local oxidation of silicon (LOCOS) layer with a shallow trench isolation (STI) structure. While such examples may be expected to reduce or avoid the operational effects of occurrence of cone defects, no particular result is a requirement unless explicitly recited in a particular claim.

An example described herein is an integrated circuit. The integrated circuit includes a semiconductor layer, a local oxidation of silicon (LOCOS) layer, a shallow trench isolation (STI) structure, and a passive circuit component. The semiconductor layer is over a substrate. The LOCOS layer is over the semiconductor layer. The STI structure extends into the semiconductor layer. The passive circuit component is over and touches the LOCOS layer.

Another example is an integrated circuit. The integrated circuit includes a semiconductor substrate, an STI structure, an active device, a LOCOS layer, and a passive circuit component. The semiconductor substrate includes silicon. The STI structure extends into the semiconductor substrate and defines, at least in part, an active area of the semiconductor substrate. The active device is disposed at least partially in the active area of the semiconductor substrate. The LOCOS layer is over the semiconductor substrate. The passive circuit component is over the LOCOS layer.

A further example is a method of forming an integrated circuit. An STI structure is formed extending from a top surface of a semiconductor substrate into the semiconductor substrate. A LOCOS layer is formed at the top surface of the semiconductor substrate. An active device is formed at least partially in an active area in the semiconductor substrate defined, at least in part, by the STI structure. A passive circuit component is formed over the LOCOS layer.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features may be understood in detail, reference is made to the following detailed description taken in conjunction with the accompanying drawings.

FIG. 1 is a cross-sectional view of an integrated circuit according to some examples.

FIG. 2 is a layout view of a local oxidation of silicon (LOCOS) layer and passive circuit component of FIG. 1 according to some examples.

FIGS. 3 through 15 are cross-sectional views of the integrated circuit of FIG. 1 at various stages of manufacturing according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. An illustrated example may not have all the aspects or advantages shown. An aspect or an advantage described in conjunction with a particular example is not necessarily limited to that example and may be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations. In the following discussion, doping levels may be described in quantitative and/or qualitative terms, wherein a doping level less than 1×10¹⁶ cm⁻³ is lightly doped, a doping level between 1×10¹⁶ cm⁻³ and 1×10¹⁸ cm⁻³ is moderately doped, a doping level between 1×10¹⁸ cm⁻³ and 1×10²⁰ cm⁻³ is heavily doped, and a doping level above 1×10²⁰ cm⁻³ is very heavily doped. A doping level at the boundaries of these ranges may be referred to qualitatively by either term referring to the higher or lower range.

The present disclosure relates generally, but not exclusively, to locating passive electrical devices in an integrated circuit (IC) over dielectric isolation that is not prone to cone defects. More particularly, the present disclosure relates generally, but not exclusively, to an integrated circuit that includes a shallow trench isolation (STI) structure extending into a semiconductor layer (e.g., a portion or layer of a semiconductor substrate) and a local oxidation of silicon (LOCOS) layer over the semiconductor layer. A passive circuit component may be formed on or over the LOCOS layer, and an active device may be formed in an active area of a semiconductor layer that is defined at least in part by the STI structure. Processing to form the LOCOS layer may be more isotropic relative to processing to form the STI structure. The more isotropic nature of the formation of the LOCOS layer may reduce or avoid occurrences of cone defects in and/or under the LOCOS layer (relative to STI structures). For example, oxidation in a LOCOS process can consume the underlying semiconductor (e.g., silicon), which may reduce or prevent formation of cone defects. Hence, stress failures of LOCOS layers, over which passive circuit components such as resistors, capacitors, etc., are disposed, may be reduced. Other benefits and advantages may be achieved.

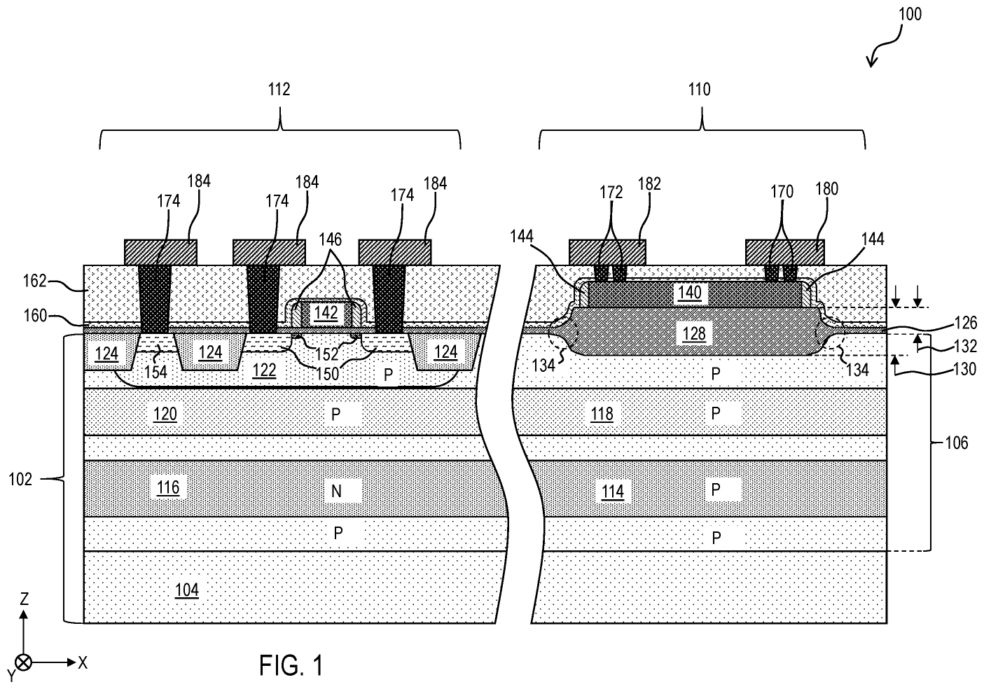

FIG. 1 is a cross-sectional view of an integrated circuit 100 according to some examples. Generally, the integrated circuit 100 includes STI structures extending into a semiconductor layer (e.g., a portion or layer of a semiconductor substrate) and a LOCOS layer on or over the semiconductor layer. An active device is disposed in, on, and/or over an active area of the semiconductor layer that is defined at least in part by an STI structure. A transistor (e.g., an n-type field effect transistor (nFET)) is illustrated in FIG. 1 and described as an example active device. Another active device and/or another transistor may be implemented as an active device in other examples. A passive circuit component is disposed on or over the LOCOS layer and may be, in whole or in part, a resistor, a capacitor, an inductor, or the like. X-Y-Z reference axes are illustrated in the figures to facilitate orientations of views in various figures.

The integrated circuit 100 includes a semiconductor substrate 102. The semiconductor substrate 102, in the illustrated example, includes a semiconductor support substrate 104 (or handle substrate or wafer) and an epitaxial layer 106. The semiconductor support substrate 104 may be a bulk semiconductor substrate, a semiconductor-on-insulator (SOI) substrate, or any other appropriate substrate. The epitaxial layer 106 includes one or more layers of semiconductor material epitaxially grown on or over the semiconductor support substrate 104. The epitaxial layer 106 may be or include one or multiple epitaxial layers of the same or different material. The epitaxial layer 106 may be or include silicon (Si), silicon germanium (SiGe), gallium arsenide (GaAs), gallium nitride (GaN), the like, or a combination thereof. In some examples, the semiconductor support substrate 104 is or includes a silicon substrate (which may be singulated from a bulk silicon wafer at the conclusion of semiconductor processing), and the epitaxial layer 106 is or includes a layer of silicon. In some examples, the epitaxial layer 106 may be omitted, and a semiconductor material of the semiconductor substrate 102 (e.g., in, on, and/or over which devices are formed) may be or include silicon. The semiconductor substrate 102 has a top major surface in, on, and/or over which devices (e.g., transistors) are generally disposed and formed.

The semiconductor substrate 102 has a passive component area 110 and an active device area 112. A passive circuit component is disposed on or over the semiconductor substrate 102 in the passive component area 110, as described in detail subsequently. In some examples, the passive circuit component is or includes, in whole or in part, a resistor, and in other examples, the passive circuit component may be or include, in whole or in part, a capacitor, inductor, or the like. An active device is disposed in, on, and/or over the semiconductor substrate 102 in the active device area 112. As stated above, an nFET is illustrated in the figures, and described in detail subsequently, as an example of an active device disposed in the active device area 112. Other active devices may be implemented as an active device in the active device area 112 in other examples.

Various doped layers or regions are disposed in the semiconductor substrate 102. Different areas or regions of the semiconductor substrate 102 may have different doped layers or regions based on one or more devices that are disposed within the respective area. The doped layers or regions described herein are merely an example, and different doped layers or regions, whether with different dopant conductivity type, different dopant concentrations, different depths, etc., may be implemented in other examples.

The epitaxial layer 106 is doped with a dopant having a first conductivity type (e.g., p-type). In some examples, the epitaxial layer 106 may be doped in situ during epitaxial growth with a p-type dopant (e.g., boron) at a concentration in a range from about 1×10¹⁴ cm⁻³ to about 5×10¹⁵ cm⁻³, e.g., lightly doped. A first deep buried layer 114 and a second deep buried layer 116 are disposed in the semiconductor substrate 102 (e.g., in the epitaxial layer 106) in the passive component area 110 and the active device area 112, respectively. A first buried layer 118 and a second buried layer 120 are disposed in the semiconductor substrate 102 (e.g., in the epitaxial layer 106) in the passive component area 110 and the active device area 112, respectively. The first deep buried layer 114 is disposed at a depth in the semiconductor substrate 102 that is greater than the depth in the semiconductor substrate 102 at which the first buried layer 118 is disposed. The second deep buried layer 116 is disposed at a depth in the semiconductor substrate 102 that is greater than the depth in the semiconductor substrate 102 at which the second buried layer 120 is disposed. As illustrated, the first buried layer 118 is disposed above and over the first deep buried layer 114 in the semiconductor substrate 102 (e.g., the semiconductor support substrate 104), and the second buried layer 120 is disposed above and over the second deep buried layer 116 in the semiconductor substrate 102 (e.g., the semiconductor support substrate 104).

In the illustrated example, the first deep buried layer 114 and the first buried layer 118 are each doped with a dopant having the first conductivity type. In some examples, the first deep buried layer 114 may be a p-type layer doped with a p-type dopant at a lightly doped concentration, and the first buried layer 118 may be a p-type layer doped with a p-type dopant at a lightly doped concentration.

In the illustrated example, the second deep buried layer 116 is doped with a dopant having a second conductivity type opposite the first conductivity type, and the second buried layer 120 is doped with a dopant having the first conductivity type. In some examples, the second deep buried layer 116 may be an n-type layer doped with an n-type dopant (e.g., phosphorous and/or arsenic) at a moderately or greater concentration, and the second buried layer 120 may be a p-type layer doped with a p-type dopant at a moderately or greater concentration.

A shallow well 122 is disposed in the semiconductor substrate 102 (e.g., in the epitaxial layer 106) in the active device area 112. The shallow well 122 extends from the top major surface of the semiconductor substrate 102 into the semiconductor substrate 102 to a depth to or above the second buried layer 120. In the illustrated example, the shallow well 122 is doped with a dopant having the first conductivity type. In some examples, the shallow well 122 may be a p-type layer doped with a p-type dopant at a moderately or greater concentration.

STI structures 124 are disposed the semiconductor substrate 102 (e.g., in the epitaxial layer 106) in the active device area 112. The STI structures 124 extend from the top major surface of the semiconductor substrate 102 into the semiconductor substrate 102, and more particularly, into the shallow well 122. The STI structures 124 may define an active area of the semiconductor substrate 102 in or on which an active device is formed. In some examples, an STI structure 124 may be formed by etching a trench into the semiconductor substrate 102 (e.g., the epitaxial layer 106) and filling the trench with one or more insulating materials. For example, an insulating liner may be formed (e.g., deposited) on or over surfaces of the semiconductor substrate 102 that define the trench, and an insulating fill material may be formed (e.g., deposited) on or over the insulating liner in the trench. In other examples, an STI structure 124 does not include an insulating liner and includes an insulating fill material in the trench. In some examples, the insulating liner may be or include a nitride, an oxide, an oxynitride, or the like, and the insulating fill material may be an oxide or other insulating material.

A top surface of an STI structure 124 may be substantially co-planar with the top major surface of the semiconductor substrate 102, such as may result from a chemical mechanical polish (CMP) of the insulating fill material. An STI structure 124, in some examples, may extend above the top major surface of the semiconductor substrate 102 less than 10 nm. This characteristic may be referred to as “substantially co-planar”. In some examples, an STI structure 124 may have a top surface that is dished below the top major surface of the semiconductor substrate 102. Processing may result in various permutations of surfaces of STI structures 124 being at, above, and/or below the top major surface of the semiconductor substrate 102 while being substantially co-planar with the top major surface of the semiconductor substrate 102.

An oxide layer 126 is disposed on or over the top major surface of the semiconductor substrate 102 in the passive component area 110 and the active device area 112, and a LOCOS layer 128 is on or over the semiconductor substrate 102 (e.g., the epitaxial layer 106) in the passive component area 110. In some examples, the LOCOS layer 128 is formed by a local oxidation process, which may include thermal oxidation of a defined area of the top major surface of the semiconductor substrate 102 to form the LOCOS layer 128. As described subsequently, the LOCOS layer 128 may include or subsume a portion of the oxide layer 126. The oxide formed from the thermal oxidation may result in a dense oxide being formed in the LOCOS layer 128. In some examples, the oxide of the LOCOS layer 128 has a greater density than the insulating fill material (e.g., oxide) of the STI structures 124. The LOCOS layer 128, in the illustrated example, has a thickness 130 from a bottom surface of the LOCOS layer 128 to a top surface of the LOCOS layer 128. The thickness 130 may be at least 60 nm. Additionally, the LOCOS layer 128 has a height 132 above the top major surface of the semiconductor substrate 102 (e.g., from the top major surface of the semiconductor substrate 102 to the top surface of the LOCOS layer 128). In some examples, the height 132 may be equal to or greater than 10 nm. Hence, in some examples, the LOCOS layer 128 has a greater topography over the top major surface of the semiconductor substrate 102 than the STI structures 124. The LOCOS layer 128, as illustrated, includes a bird's beak region 134 at respective lateral edges of the LOCOS layer 128 where the LOCOS layer 128 laterally meets the oxide layer 126. A bird's beak region 134 may have various profiles depending on process conditions used to form the LOCOS layer 128, for example.

A passive circuit component 140 is disposed on or over the LOCOS layer 128 in the passive component area 110. In some examples, the passive circuit component 140 is or includes a conductive structure, such as a doped polysilicon structure and/or a metal-containing structure (e.g., a metal, a metal alloy, a metal-semiconductor compound, etc.). In examples in which the conductive structure is or includes a metal-containing structure, the metal-containing structure may include nickel chromium, nickel chromium aluminum, silicon chromium, carbon-doped silicon chromium, silicon chromium aluminum, tantalum nitride, titanium nitride, a metal-silicon compound (e.g., a metal silicide), a metal-germanium compound, and/or a ceramic metal (e.g., cermet). In some examples, the passive circuit component 140 forms at least part of a resistor structure. In some examples, the passive circuit component 140 may form at least part of a plate of a capacitor, a conductive path of an inductor, or another portion of a passive circuit component. In examples in which the passive circuit component 140 is a doped polysilicon structure, the doped polysilicon structure may be doped with a dopant having the first or second conductivity type, and may be doped at any concentration determined to result in a desired conductivity of the polysilicon layer. In some examples in which the passive circuit component 140 forms at least part of a resistor structure, the passive circuit component 140 may have a sheet resistance of 7.0 ohms/square or greater, for example. A breakdown voltage of the LOCOS layer 128 from a voltage difference between the passive circuit component 140 and the semiconductor substrate 102 (e.g., epitaxial layer 106) may be at least about 10 V.

A gate structure 142 is disposed on or over the oxide layer 126 in the active device area 112. The gate structure 142 is disposed over an active area of the semiconductor substrate 102 defined by the STI structures 124. In some examples, the gate structure 142 is or includes a conductive structure, such as a doped polysilicon structure. In some examples, the gate structure 142 may be or include any appropriate conductive material, such as polysilicon (e.g., doped polysilicon), metal (e.g., tungsten (W), aluminum (Al), titanium (Ti), tantalum (Ta), or the like), a semiconductor-metal compound (e.g., silicide), the like, or a combination thereof. In examples in which the gate structure 142 is a doped polysilicon structure, the doped polysilicon structure may be doped with a dopant having the first or second conductivity type, and may be moderately to very heavily doped.

Spacers 144 are disposed along respective sidewalls of the passive circuit component 140, and spacers 146 are disposed along respective sidewalls of the gate structure 142. The spacers 144, 146 may be any appropriate dielectric material, such as a nitride (e.g., silicon nitride), oxynitride, or the like. In some examples the spacers 144, 146 may be omitted, such as when the passive circuit component 140 employs a metal-containing structure such as TiN.

Source/drain regions 150 are disposed in the semiconductor substrate 102 (e.g., epitaxial layer 106) in the active area defined by STI structures 124 and on opposing sides of the gate structure 142. Each source/drain region 150 may extend laterally from a sidewall of a respective spacer 146 (laterally distal from the gate structure 142) and/or from underlying the respective spacer 146 to an STI structure 124 that in part defines the active area. The source/drain regions 150 extend from the top major surface of the semiconductor substrate 102 into the shallow well 122 in the semiconductor substrate 102. In the illustrated example, the source/drain regions 150 are doped with a dopant having the second conductivity type. In some examples, the source/drain regions 150 may be n-type and heavily or very heavily doped.

Extension regions 152 (e.g., lightly doped drain (LDD) regions) are disposed in the semiconductor substrate 102 (e.g., epitaxial layer 106) in the active area defined by STI structures 124 and on opposing sides of the gate structure 142. Each extension region 152 may extend laterally from a sidewall of the gate structure 142 and/or from underlying the gate structure 142 to a respective source/drain region 150. A channel region is under the gate structure 142 extends between the extension regions 152, and further, between the source/drain regions 150. The extension regions 152 extend from the top major surface of the semiconductor substrate 102 into the shallow well 122 in the semiconductor substrate 102. In the illustrated example, the extension regions 152 are doped with a dopant having the second conductivity type. In some examples, the extension regions 152 may be an n-type region doped with an n-type dopant at a concentration in a range from about 1×10¹⁸ cm⁻³ to about 5×10¹⁹ cm⁻³, e.g., heavily doped.

A body contact region 154 is disposed in the semiconductor substrate 102 (e.g., epitaxial layer 106) between STI structures 124. The body contact region 154 extends from the top major surface of the semiconductor substrate 102 into the shallow well 122 in the semiconductor substrate 102. In the illustrated example, the body contact region 154 is doped with a dopant having the first conductivity type. In some examples, the body contact region 154 may be p-type and heavily or very heavily doped.

In the illustrated example, the nFET (e.g., the example active device) includes the source/drain regions 150 and gate structure 142. The nFET, or other active device in other examples, is spaced apart from the LOCOS layer 128 by, among other things, at least one STI structure 124.

A conformal dielectric layer 160 is disposed conformally on or over the oxide layer 126, LOCOS layer 128, passive circuit component 140, gate structure 142, and spacers 144, 146. The conformal dielectric layer 160 may be any appropriate dielectric material, such as a nitride (e.g., silicon nitride), oxynitride, or the like. In some examples, the conformal dielectric layer 160 may be an etch stop layer. An inter-layer dielectric layer 162, or pre-metal dielectric (PMD), is disposed on or over the conformal dielectric layer 160. The inter-layer dielectric layer 162 may be or include a silicon-oxide based material such as a phosphosilicate glass (PSG).

Metal contacts 170, 172, 174 are disposed through the inter-layer dielectric layer 162 and the conformal dielectric layer 160. One or more metal contacts 170 provide an ohmic electrical connection to the passive circuit component 140 at a first end of the passive circuit component 140, and one or more metal contacts 172 provide an ohmic electrical connection to the passive circuit component 140 at a second end of the passive circuit component 140 opposite from the first end. Respective metal contacts 174 contact a respective source/drain regions 150, and a metal contact 174 contacts the body contact region 154. Each of the metal contacts 170, 172, 174 may include a barrier and/or adhesion layer (e.g., titanium nitride (TiN), tantalum nitride (TaN), the like, or a combination thereof) conformally in a respective opening through the inter-layer dielectric layer 162 and the conformal dielectric layer 160, and a conductive fill material (e.g., a metal, such as tungsten (W), copper (Cu), a combination thereof, or the like). The metal contacts 170, 172, 174 may also include, if contacting a semiconductor material (e.g., the epitaxial layer 106 or polysilicon of the passive circuit component 140 or gate structure 142, if implemented), a semiconductor-metal compound (e.g., silicide) at the surface of the semiconductor material.

Metal lines 180, 182, 184 are disposed on or over the inter-layer dielectric layer 162. The metal line 180 provides a conductive electrical connection to the one or more metal contacts 170, and the metal line 182 provides a conductive electrical connection to the one or more metal contacts 172. Each metal line 184 contacts a respective metal contact 174. The metal lines 180, 182, 184 may be or include any metal material (e.g., aluminum (Al), copper (Cu), tungsten (W), a combination thereof, or the like). Additional dielectric layers, via levels, and metal levels may be disposed over the inter-layer dielectric layer 162 and metal lines 180, 182, 184. The active device (e.g., nFET in the illustrated example) may be electrically connected to the passive circuit component 140 through one or more metal levels and via levels disposed over the inter-layer dielectric layer 162 and metal lines 180, 182, 184. The passive circuit component 140 and the active device may together form at least a part of an electrical circuit in the integrated circuit 100.

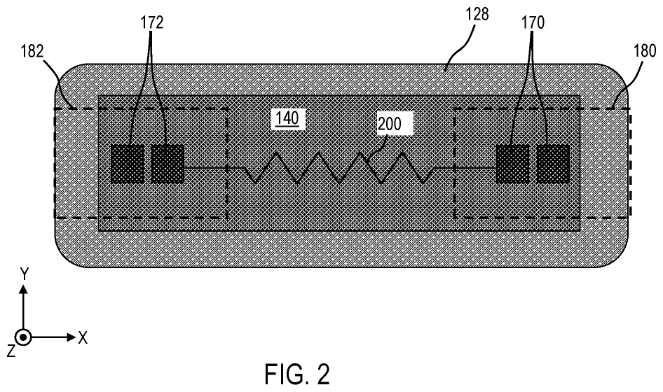

FIG. 2 is a layout view of the LOCOS layer 128 and passive circuit component 140 according to some examples. The lateral boundaries of the LOCOS layer 128 extend beyond the lateral boundaries of the passive circuit component 140. In the illustrated example, the passive circuit component 140 forms a resistor, illustrated schematically by resistor 200, between the one or metal contacts 170 and the one or more metal contacts 172. In other examples, the metal contacts 172 may be omitted, such as where the passive circuit component 140 forms a plate of a capacitor.

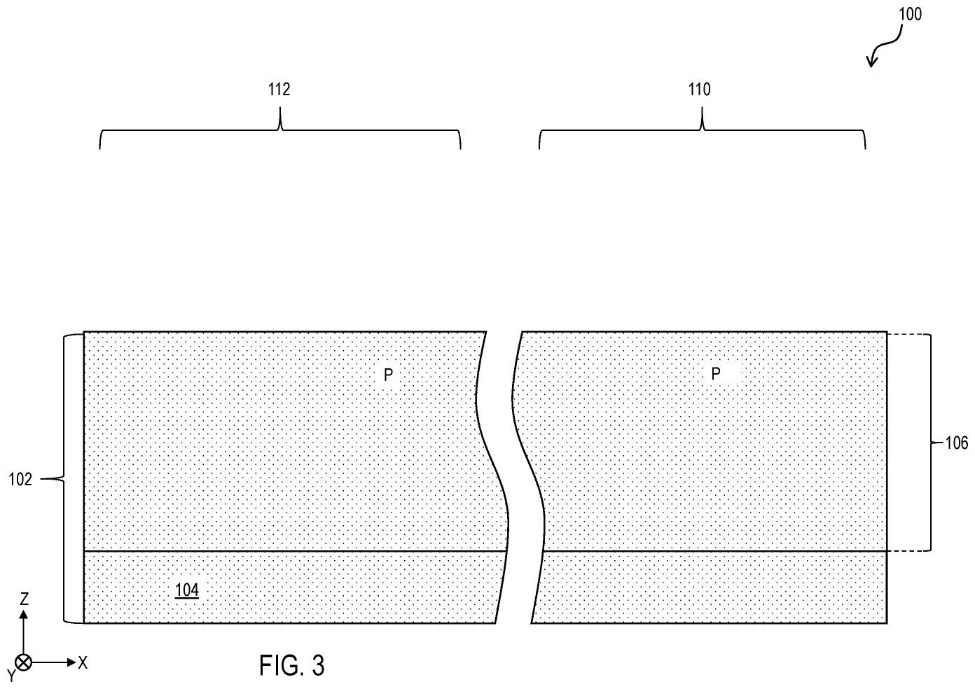

Turning now to FIGS. 3 through 15, the integrated circuit 100 is illustrated in cross-sectional views at various stages of manufacturing according to an example method. Referring to FIG. 3, the epitaxial layer 106 is formed on or over the semiconductor support substrate 104 to form the semiconductor substrate 102. In some examples, the semiconductor support substrate 104 is a bulk silicon wafer. The epitaxial layer 106 may be formed using an epitaxial growth by an appropriate epitaxial growth process, such as low pressure chemical vapor deposition (LPCVD) or the like. In some examples, the epitaxial layer 106 is predominantly silicon. The epitaxial layer 106 is doped, such as by in situ during the epitaxial growth. The dopant type and concentration of the dopant in the epitaxial layer 106 may be as described above. As stated previously, the epitaxial layer 106 may be omitted in some examples.

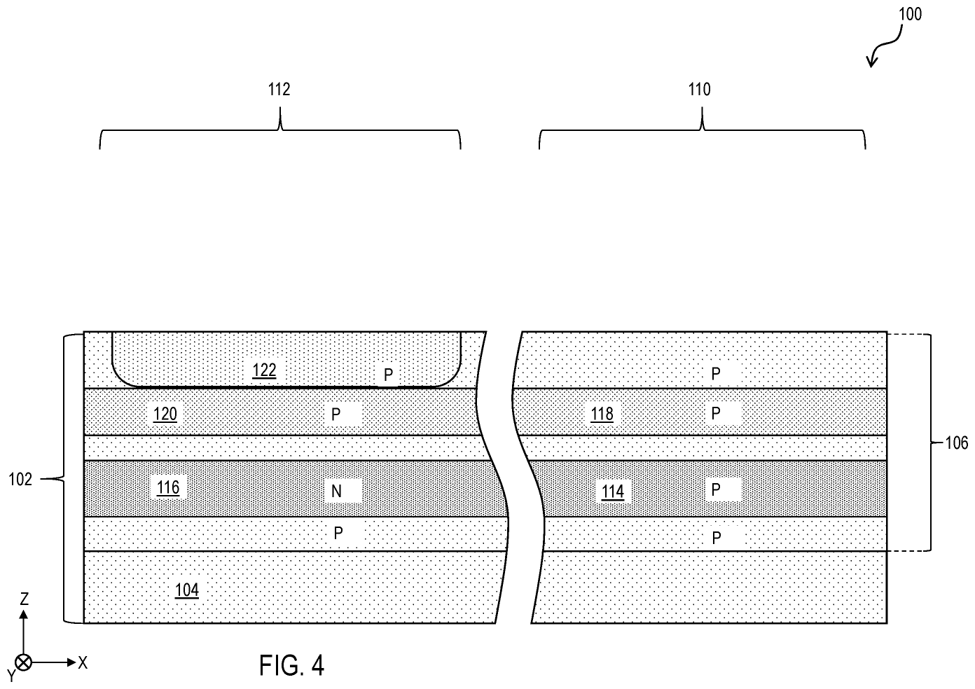

Referring to FIG. 4, the first deep buried layer 114, second deep buried layer 116, first buried layer 118, second buried layer 120, and shallow well 122 are formed in the semiconductor substrate 102 (e.g., in the epitaxial layer 106). The deep buried layers 114, 116, buried layers 118, 120, and shallow well 122 may be formed by implanting respective dopants into the semiconductor substrate 102 (e.g., the epitaxial layer 106). Any portion of the semiconductor substrate 102 that is not to be implanted by a dopant during a given implantation may be masked, such as by a patterned photoresist, during that implantation. The dopant type and concentration of the first deep buried layer 114, second deep buried layer 116, first buried layer 118, second buried layer 120, and shallow well 122 are as described above. In some examples the epitaxial layer 106 may be formed in two or more stages to facilitate formation of the buried layers.

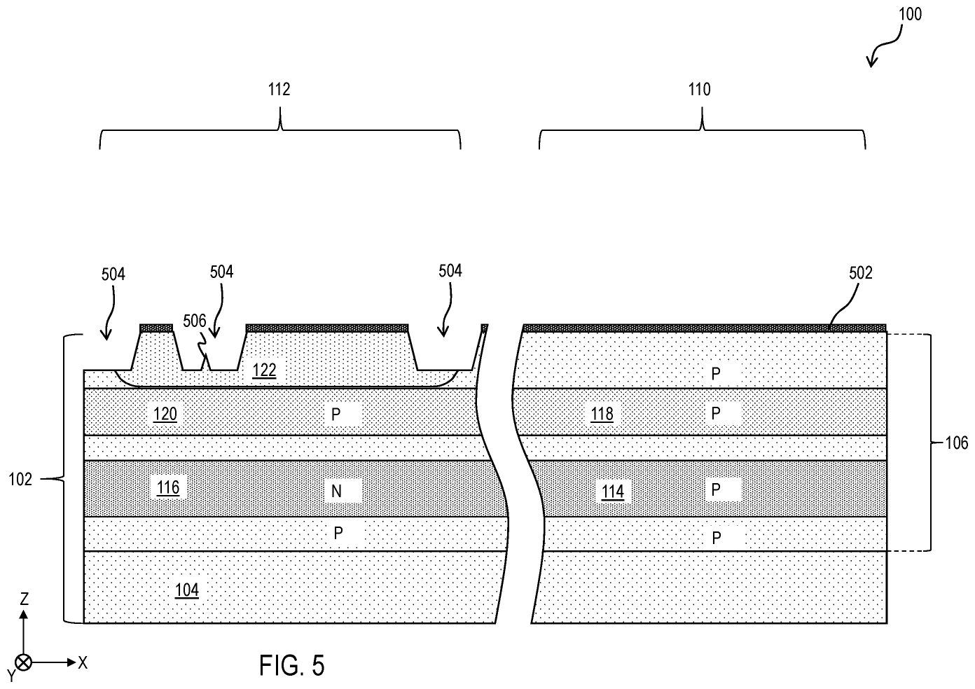

Referring to FIG. 5, a patterned mask 502 is formed on or over the semiconductor substrate 102, and using the patterned mask 502, trenches 504 are etched in the semiconductor substrate 102 (e.g., the epitaxial layer 106). The patterned mask 502 may include a hardmask, such as a nitride layer (e.g., silicon nitride, titanium nitride, tantalum nitride, or the like). The patterned mask 502 may be formed by depositing a hardmask layer on or over the semiconductor substrate 102, such as by plasma enhanced chemical vapor deposition (PECVD) or another deposition process. The hardmask layer may then be patterned using appropriate photolithography and etch processes. The etch process may be a dry, anisotropic etch process, such as reactive ion etching (ME) or the like. With the patterned mask 502, a dry, anisotropic etch process, such as ME or the like, is performed to etch the trenches 504 into the semiconductor substrate 102 (e.g., the epitaxial layer 106).

A cone defect 506 (shown in FIG. 5 solely as an example for clarity although not illustrated in other figures) exemplifies such defects that may be present after the trench etch. Cone defects may have any height, and may be as high as the trenches 504 are deep. When present under a conductive circuit feature, large cone defects may result in infant failure of the IC. In contrast a smaller cone defect may never result in circuit failure, or may cause dielectric breakdown of the insulating fill material after a period of operation, possibly resulting in a field failure.

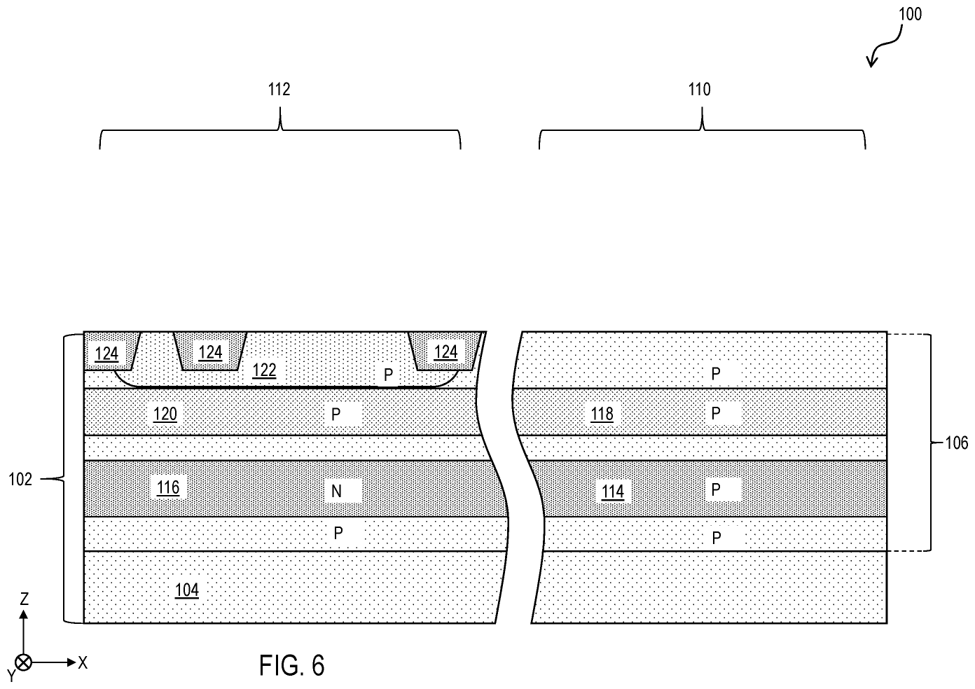

Referring to FIG. 6, STI structures 124 are formed in respective trenches 504. The STI structures 124 may be formed by depositing, such as by PECVD, high density plasma chemical vapor deposition (HDP-CVD), atomic layer deposition (ALD), or the like, an insulating liner layer on or over the semiconductor substrate 102 and along surfaces of the trenches 504, and depositing, by flowable chemical vapor deposition (FCVD) or the like, an insulating fill material on or over the insulating liner layer. In some examples, the insulating liner layer may be omitted. Excess insulating fill material, excess insulating liner layer, and the patterned mask 502 may be removed by a planarization process, such as a CMP, thereby forming the STI structures 124 with respective top surfaces substantially co-planar with the top major surface of the semiconductor substrate 102, as described above.

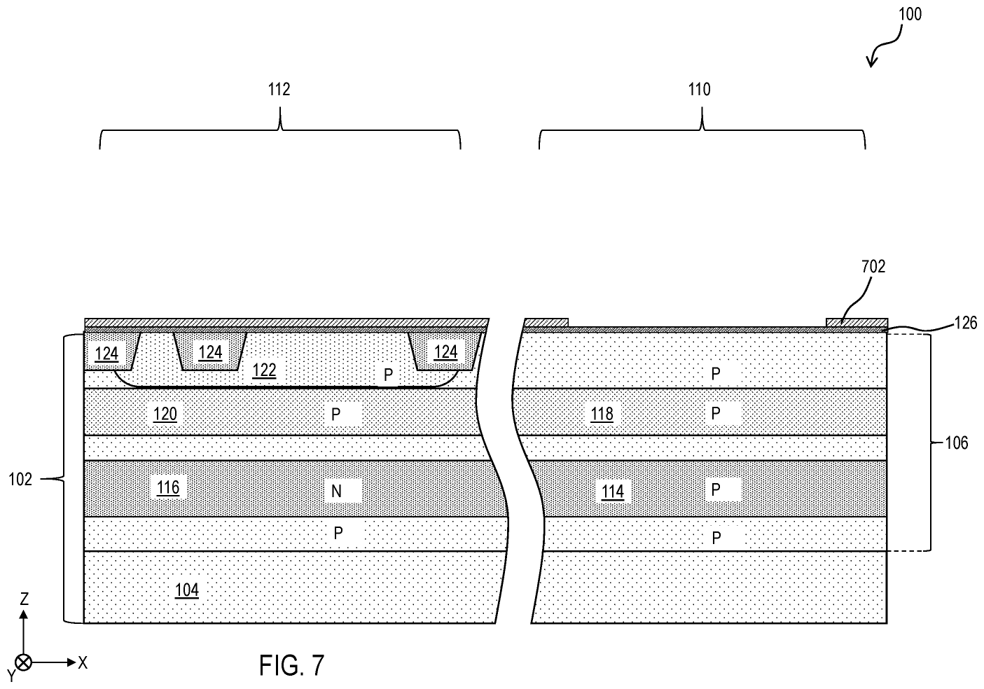

Referring to FIG. 7, an oxide layer 126 is formed on a top major surface of the semiconductor substrate 102. In some examples, the oxide layer 126 is formed by performing an oxidation process to oxidize the semiconductor material (e.g., silicon) at the top major surface of the semiconductor substrate 102. Hence, in such examples, the oxide layer 126 may be an oxide of the semiconductor material of the semiconductor substrate 102 (e.g., the epitaxial layer 106), such as silicon oxide. For example, the oxidation process may include a thermal oxidation performed at an elevated temperature while flowing a gas comprising oxygen (02), ozone (03), steam (H₂O), the like, or a combination thereof. In other examples, the oxide layer 126 may be deposited over the semiconductor substrate 102 using an appropriate deposition process, such as, for example, PECVD, HDP-CVD, ALD, or the like.

A patterned mask 702 is formed over the oxide layer 126. An opening in the patterned mask 702 exposes an area of the oxide layer 126 where a LOCOS layer 128 will be formed. In some examples, the patterned mask 702 is a nitride, such as silicon nitride. The patterned mask 702 may be deposited by any appropriate deposition process, such as PECVD or the like, and patterned using appropriate photolithography and etch processes. In some examples, the etch process may be isotropic (such as a wet etch using phosphoric acid (H₃PO₄)).

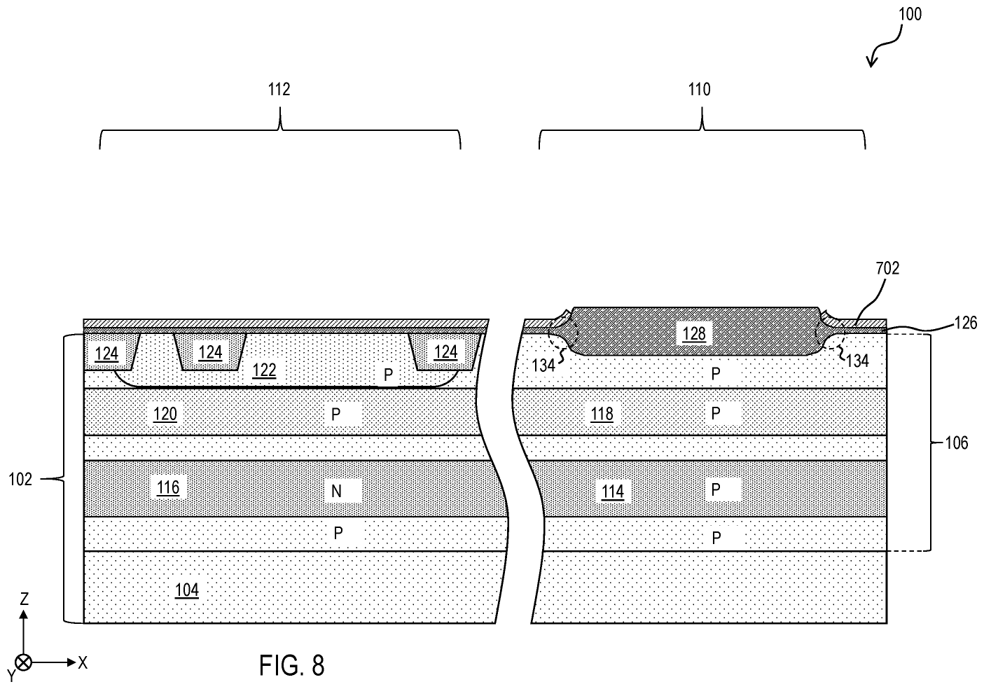

Referring to FIG. 8, an oxidation process is performed to form the LOCOS layer 128. The oxidation process further oxidizes the semiconductor material (e.g., silicon) at the top major surface of the semiconductor substrate 102 to form the LOCOS layer 128. Generally, the opening through the patterned mask 702 allows vertical penetration and diffusion of oxygen through the oxide layer 126 and into the semiconductor substrate 102 such that oxidation of the semiconductor material occurs at the opening. The presence of the patterned mask 702 generally inhibits or reduces vertical penetration and diffusion of oxygen. However, oxygen may diffuse laterally from the openings to oxidize portions of the semiconductor material at edges of the opening and underlying the patterned mask 702. This lateral diffusion and resulting oxidation forms, at least in part, the bird's beak regions 134. In some examples, the oxidation process may include a thermal oxidation performed at an elevated temperature while flowing a gas comprising oxygen (O₂), ozone (O₃), steam (H₂O), the like, or a combination thereof.

Cone defects can be avoided or reduced at a LOCOS layer 128 by the above-described processing. Using isotropic (e.g., wet) etching to pattern the patterned mask 702 can mitigate against a particle or residue of a photoresist being present where the hardmask layer is to be etched. The isotropic etch can undercut and remove the hardmask underlying the particle or residue, which may cause the hardmask layer to be appropriately patterned. Comparatively, if an anisotropic etch is used, the particle or residue may generally not be undercut, and hence, the particle or residue, and underlying hardmask layer, may not be removed. The particle or residue may act as a mask to prevent the underlying substrate from being etched, which, in an STI process, may result in a cone defect in the STI structure.

Returning to the LOCOS process, even if after forming the patterned mask 702 some particle or residue remains on the oxide layer 126 where the LOCOS layer 128 is to be formed, the oxidation process is expected to permit some amount of lateral diffusion of oxygen into the semiconductor substrate 102 thereby mitigating against the formation of a cone defect. Comparatively, if after forming a patterned hardmask layer in an STI process some particle or residue remains on the semiconductor substrate where a trench is to be etched for an STI structure, the particle or residue may act as a mask resulting in a cone defect, and subsequent deposition of an insulating material may not mitigate the cone defect. Accordingly, LOCOS processing, as described by example above, may provide a LOCOS layer that reduces or avoids occurrences of defects that could otherwise result in forming a short between the passive component 140 and the epitaxial layer 106.

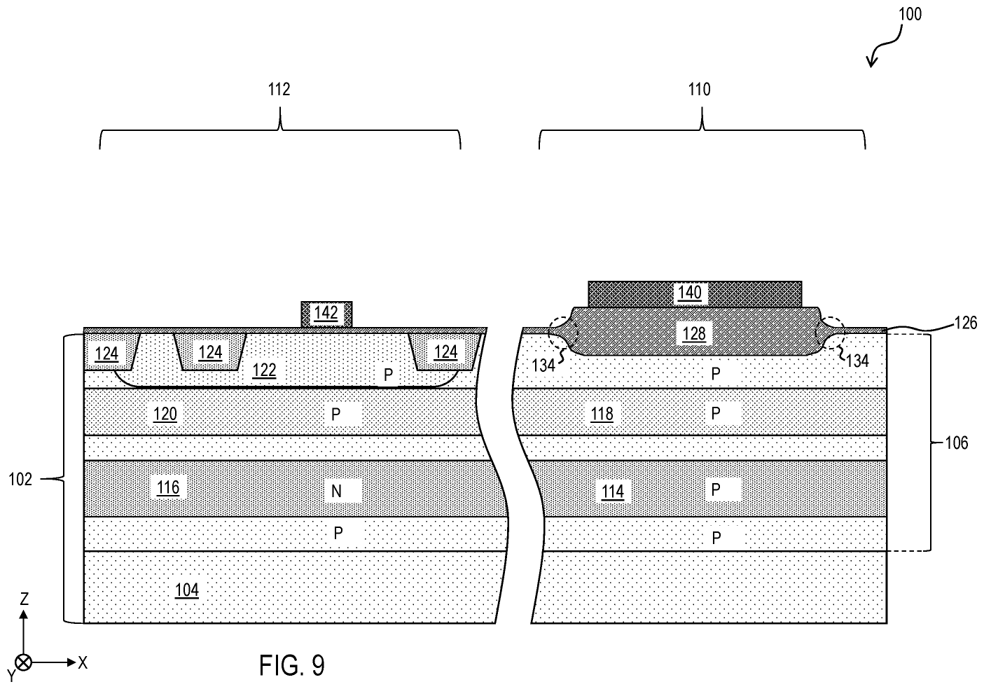

Referring to FIG. 9, the patterned mask 702 is removed. For example, the patterned mask 702 may be removed using an etch process, such as a wet etch using phosphoric acid (H₃PO₄).

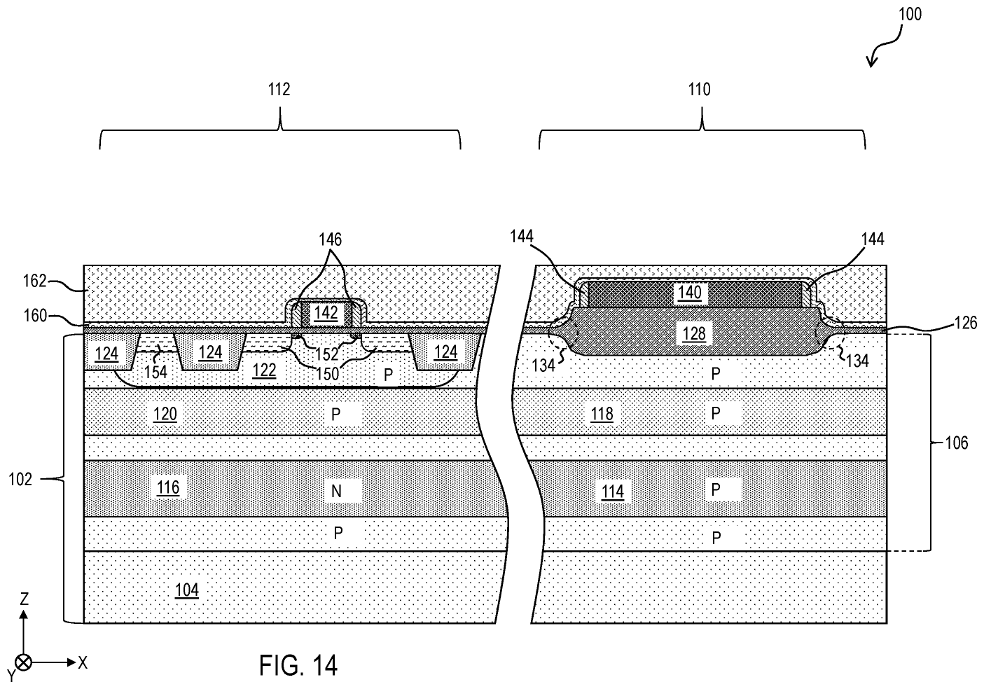

Subsequently, the passive circuit component 140 is formed on the LOCOS layer 128 in the passive component area 110, and the gate structure 142 is formed on the oxide layer 126 in the active device area 112. In some examples, the passive circuit component 140 and the gate structure 142 are each a doped polysilicon structure. In such examples, a polysilicon layer may be deposited, such as by chemical vapor deposition (CVD), physical vapor deposition (PVD), or the like, on or over the oxide layer 126 and the LOCOS layer 128. The polysilicon layer may be implanted with a dopant. The dopant type and concentration of the passive circuit component 140 and the gate structure 142 are as described above. The doped polysilicon layer may then be patterned into the passive circuit component 140 and the gate structure 142 using appropriate photolithography and etch processes. The etch process may be an anisotropic etch, such as an RIE. In some examples in which the passive circuit component 140 is to include a metal-containing structure, a metal-containing layer is deposited and patterned to form the passive circuit component 140 (and/or the gate structure 142) of FIG. 9. In other examples, the passive circuit component 140 of FIG. 9 may be formed as a dummy passive circuit component 140, which is removed after forming the nFET (e.g., subsequent to FIG. 14 described subsequently). In such examples, a replacement passive circuit component 140 including a metal-containing structure may be formed where the dummy passive circuit component 140 was removed. Such processing may be similar to a replacement gate process.

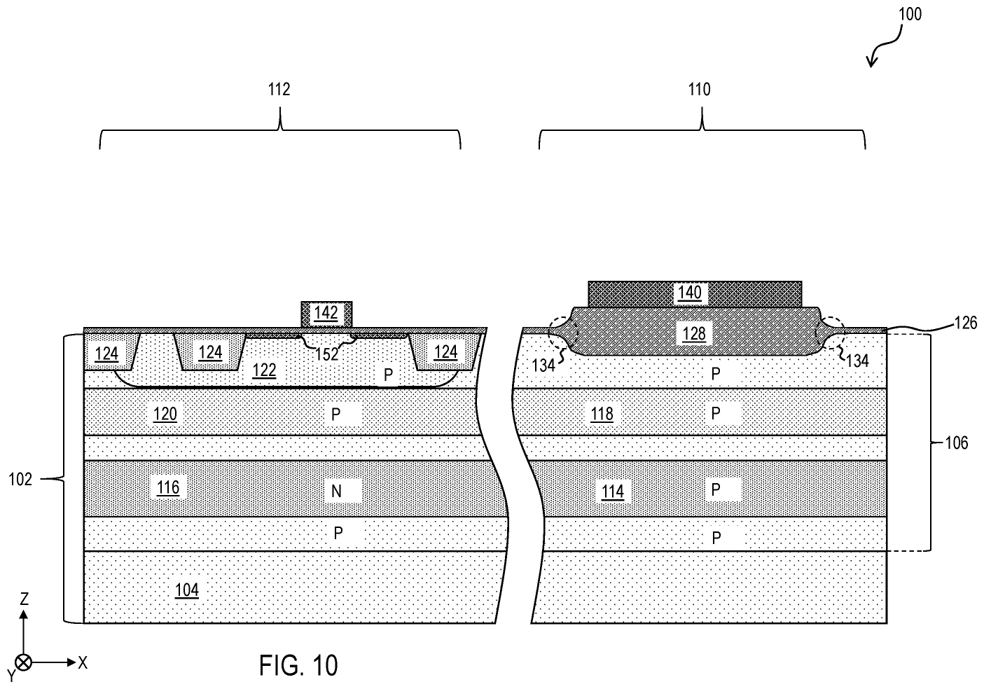

Referring to FIG. 10, extension regions 152 are formed in the semiconductor substrate 102 (e.g., in the epitaxial layer 106). The extension regions 152 may be formed by implanting dopants into the semiconductor substrate 102 (e.g., the epitaxial layer 106). Generally, outside of the active area in which the extension regions 152 are formed, any portion of the semiconductor substrate 102 that is not to be implanted by the dopant during the implantation may be masked, such as by a patterned photoresist, during that implantation. The gate structure 142 may mask the channel in the active area from being implanted with dopants. The dopant type and concentration of the extension regions 152 are as described above.

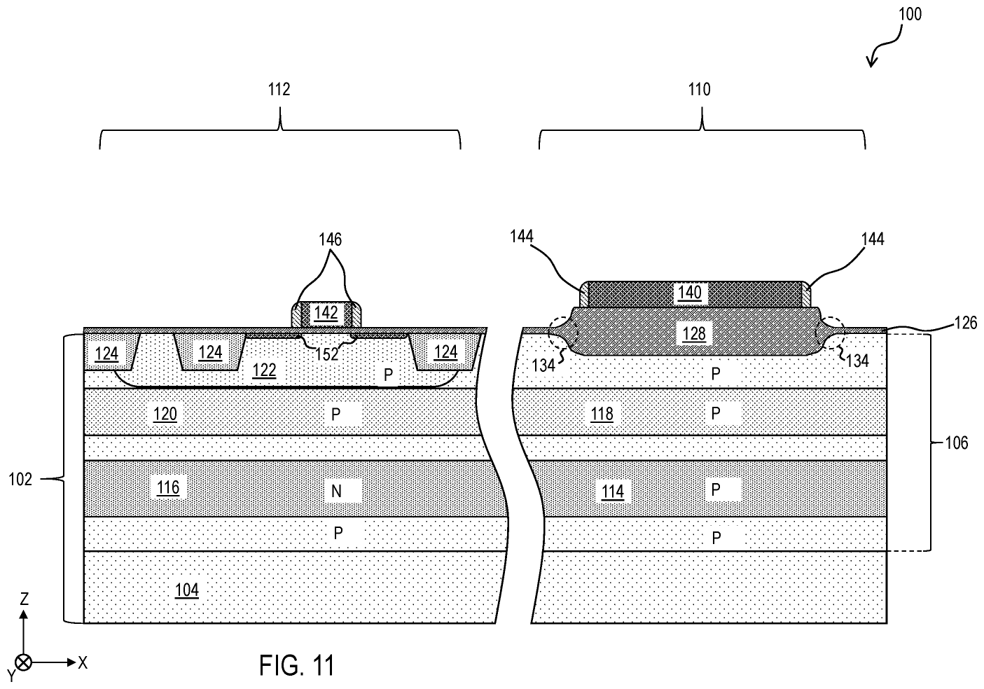

Referring to FIG. 11, spacers 144 are formed along sidewalls of the passive circuit component 140, and spacers 146 are formed along sidewalls of the gate structure 142. The spacers 144, 146 may be formed by conformally depositing a spacer layer on or over the oxide layer 126, the LOCOS layer 128, the passive circuit component 140, and the gate structure 142. The spacer layer may then be anisotropically etched, such as by RIE or the like, to remove horizontal portions of the spacer layer while vertical portions of the spacer layer remain as the spacers 144, 146.

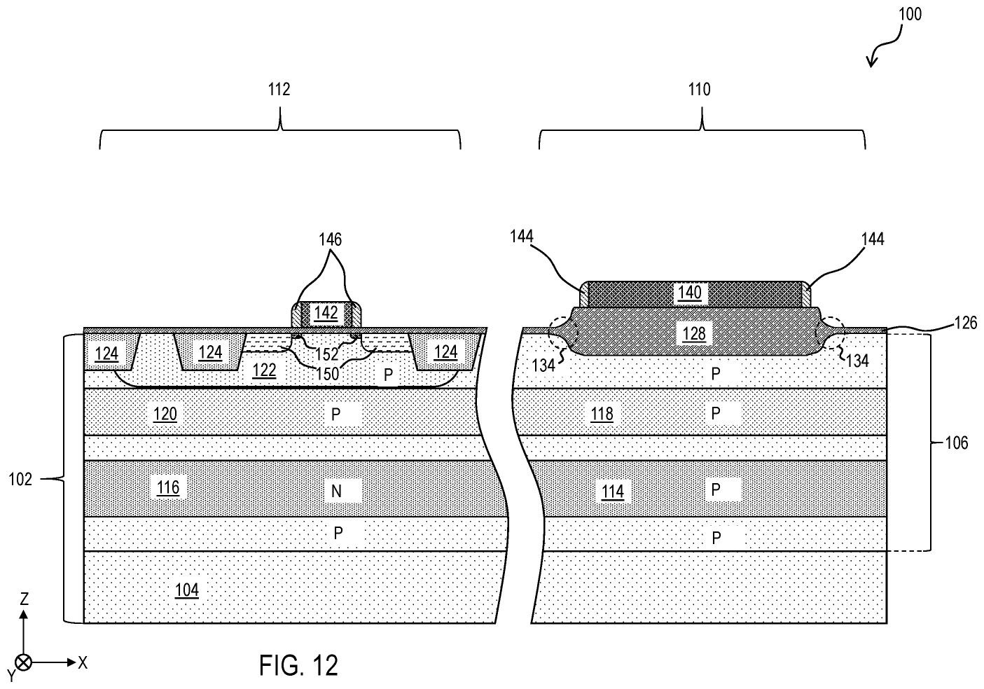

Referring to FIG. 12, source/drain regions 150 are formed in the semiconductor substrate 102 (e.g., in the epitaxial layer 106). The source/drain regions 150 may be formed by implanting dopants into the semiconductor substrate 102 (e.g., the epitaxial layer 106). Generally, outside of the active area in which the source/drain regions 150 are formed, any portion of the semiconductor substrate 102 that is not to be implanted by the dopant during the implantation may be masked, such as by a patterned photoresist, during that implantation. The gate structure 142 and spacers 146 may mask the channel in the active area from being implanted with dopants. The dopant type and concentration of the source/drain regions 150 are as described above.

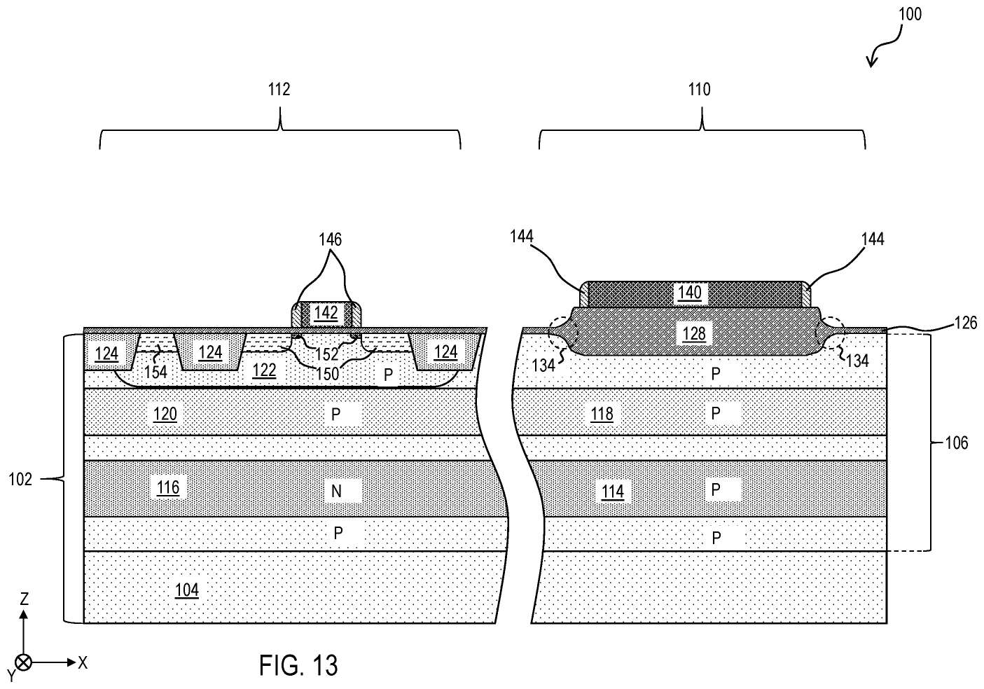

Referring to FIG. 13, body contact region 154 is formed in the semiconductor substrate 102 (e.g., in the epitaxial layer 106). The body contact region 154 may be formed by implanting dopants into the semiconductor substrate 102 (e.g., the epitaxial layer 106). Generally, outside of the active area in which the body contact region 154 are formed, any portion of the semiconductor substrate 102 that is not to be implanted by the dopant during the implantation may be masked, such as by a patterned photoresist, during that implantation. The dopant type and concentration of the body contact region 154 are as described above.

Referring to FIG. 14, the conformal dielectric layer 160 and inter-layer dielectric layer 162 are formed on or over the semiconductor substrate 102. The conformal dielectric layer 160 is conformally deposited, such as by PECVD, ALD, or the like, on or over the oxide layer 126, LOCOS layer 128, passive circuit component 140, gate structure 142, and spacers 144, 146. The inter-layer dielectric layer 162 is deposited, such as by PECVD or the like, on or over the conformal dielectric layer 160.

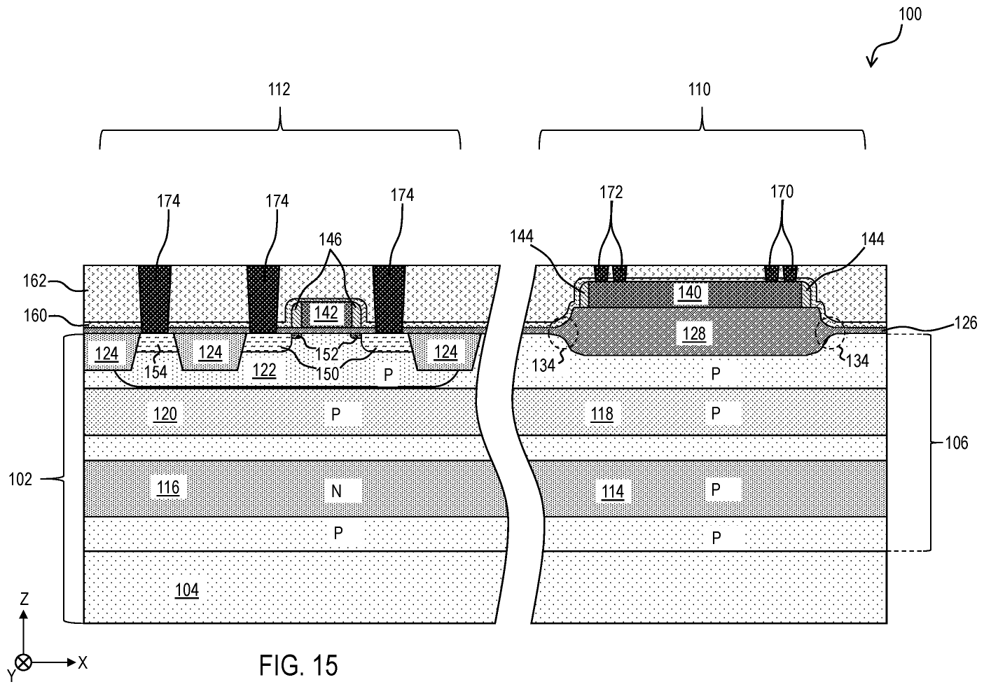

Referring to FIG. 15, metal contacts 170, 172, 174 are formed through the inter-layer dielectric layer 162 and conformal dielectric layer 160. Openings are formed through the inter-layer dielectric layer 162 and conformal dielectric layer 160 using photolithography and etch processes. Respective openings expose the first and second ends of the passive circuit component 140, the source/drain regions 150, and the body contact region 154. A metal-semiconductor compound may be formed on the source/drain regions 150 and the body contact region 154, and if, for example, polysilicon is implemented as the passive circuit component 140, on the passive circuit component 140 before the conformal dielectric layer 160 is formed and/or after forming the openings through the inter-layer dielectric layer 162 and conformal dielectric layer 160. The metal-semiconductor compound may be formed by depositing a metal, such as by CVD, PVD, or the like, on the respective regions (e.g., before the conformal dielectric layer 160 is formed or through the respective openings) and reacting the semiconductor material of the doped regions 150, 154 and, if appropriate, the passive circuit component 140 using an anneal. A barrier and/or adhesion layer may be conformally deposited, such as by CVD, ALD, or the like, in the openings, and a fill metal may be deposited, such as by CVD, PVD, or the like, on the barrier and/or adhesion layer. Any barrier and/or adhesion layer and fill material on the top surface of the inter-layer dielectric layer 162 may be removed by CMP, for example. Hence, each of the metal contacts 170, 172, 174 may include a semiconductor-metal compound, a barrier and/or adhesion layer, and a fill metal.

Referring back to FIG. 1, metal lines 180, 182, 184 are formed on or over the inter-layer dielectric layer 162 and the metal contacts 170, 172, 174. A layer of metal may be deposited on or over the inter-layer dielectric layer 162 and the metal contacts 170, 172, 174 and subsequently patterned into the metal lines 180, 182, 184. The layer of metal may be deposited by CVD, PVD, or the like, and may be patterned using appropriate photolithography and etch processes. Additional processing, such as back-end-of-the-line (BEOL) processing, may be performed.

Although various examples have been described in detail, it should be understood that various changes, substitutions, and alterations may be made therein without departing from the scope defined by the appended claims.

What is claimed is:

1. An integrated circuit comprising:
a semiconductor layer over a substrate;
a local oxidation of silicon (LOCOS) layer over the semiconductor layer;
a shallow trench isolation (STI) structure extending into the semiconductor layer; and
a passive circuit component over and touching the LOCOS layer.

2. The integrated circuit of claim 1 further comprising a transistor formed in or over the semiconductor layer and forming an electrical circuit with the passive circuit component.

3. The integrated circuit of claim 1 further comprising a transistor formed in or over the semiconductor layer and spaced apart from the LOCOS layer by the STI structure.

4. The integrated circuit of claim 1, wherein the passive circuit component includes a resistor.

5. The integrated circuit of claim 1, wherein the passive circuit component includes polysilicon.

6. The integrated circuit of claim 1, wherein the LOCOS layer has a thickness of at least 60 nm.

7. The integrated circuit of claim 1, wherein a breakdown voltage between the passive circuit component and the semiconductor layer is at least about 10 V.

8. The integrated circuit of claim 1, wherein the STI structure includes an insulating fill material, the insulating fill material having a density that is less than a density of the LOCOS layer.

9. The integrated circuit of claim 1, wherein the STI structure is substantially co-planar with a top surface of the semiconductor layer, and the LOCOS layer has a height of equal to or greater than 10 nm from the top surface of the semiconductor layer.

10. An integrated circuit comprising:
a semiconductor substrate comprising silicon;
a shallow trench isolation (STI) structure extending into the semiconductor substrate and defining, at least in part, an active area of the semiconductor substrate;
an active device disposed at least partially in the active area of the semiconductor substrate;
a local oxidation of silicon (LOCOS) layer over the semiconductor substrate; and
a passive circuit component over the LOCOS layer.

11. The integrated circuit of claim 10, wherein the semiconductor substrate comprises a support substrate and an epitaxial layer over the support substrate, the epitaxial layer comprising silicon.

12. The integrated circuit of claim 10, wherein the active device includes a transistor, the transistor and the passive circuit component forming at least a portion of an electrical circuit.

13. The integrated circuit of claim 10, wherein the passive circuit component includes a resistor.

14. The integrated circuit of claim 10, wherein the LOCOS layer has a thickness of at least 60 nm.

15. The integrated circuit of claim 10, wherein a breakdown voltage between the passive circuit component and the semiconductor substrate is at least about 10 V.

16. The integrated circuit of claim 10, wherein the STI structure includes an insulating fill material, the insulating fill material having a density that is less than a density of the LOCOS layer.

17. The integrated circuit of claim 10, wherein the STI structure is substantially co-planar with a top surface of the semiconductor substrate, and the LOCOS layer has a height of equal to or greater than 10 nm from the top surface of the semiconductor substrate.

18. A method of forming an integrated circuit, the method comprising:
forming a shallow trench isolation (STI) structure extending from a top surface of a semiconductor substrate into the semiconductor substrate;
forming a local oxidation of silicon (LOCOS) layer at the top surface of the semiconductor substrate;
forming an active device at least partially in an active area in the semiconductor substrate defined, at least in part, by the STI structure; and
forming a passive circuit component over the LOCOS layer.

19. The method of claim 18, wherein forming the STI structure comprises:
etching a trench into the semiconductor substrate; and
depositing an insulating fill material into the trench, the STI structure including the insulating fill material deposited in the trench.

20. The method of claim 18, wherein forming the LOCOS layer comprises performing an oxidation of the semiconductor substrate.
